(19) United States
(12) Patent Application Publication
(10) Pub. No.: US 2015/0257211 A1
(43) Pub. Date: Sep. 10, 2015

(54) SOLID STATE LIGHTING APPARATUSES AND RELATED METHODS

(71) Applicant: Cree, Inc., Durham, NC (US)

(72) Inventors: Jeremy Allen Johnson, Fuquay Varina, NC (US); Christopher P. Hussell, Cary, NC (US); Praneet Athalye, Morrisville, NC (US); Craig William Hardin, Apex, NC (US)

(21) Appl. No.: 14/221,839

(22) Filed: Mar. 21, 2014

Related U.S. Application Data
(63) Continuation of application No. 29/484,053, filed on Mar. 5, 2014.
Application No. 29/484,053 is a continuation of application No. 29/484,056, filed on Mar. 5, 2014.
(60) Provisional application No. 61/948,359, filed on Mar. 5, 2014.

(51) Int. Cl. H05B 33/08; H01L 25/00; H01L 33/00

(52) U.S. Cl. CPC H05B 33/089; H01L 33/005; H01L 25/50

(57) ABSTRACT

Solid state lighting apparatuses and related methods are disclosed. In one aspect, a solid state lighting apparatus is provided. The apparatus includes a substrate, one or more surge protection components supported by the substrate, and at least one solid state light emitter supported by the substrate. The surge protection components are adapted to receive alternating current (AC) directly from an AC power source. The at least one solid state light emitter electrically coupled to the one or more surge protection components. An overall height of the apparatus is approximately 4.5 millimeters (mm) or less. In some aspects, an overall surface area of the one or more surge protection components is approximately 168 square millimeters (mm²) or less. Surge protection circuitry described herein offers a compact form factor, compact surface area, is thin, and meets or exceeds surge compatibility standards.

### CROSS REFERENCE TO RELATED APPLICATIONS

This application is claims priority to U.S. Provisional Patent Application Ser. No. 61/948,359, filed on Mar. 5, 2014, and U.S. Design application Ser. Nos. 29/484,053 and 29/484,056, also filed on Mar. 5, 2014, the disclosures of each of which is incorporated herein by reference in the entirety.

### TECHNICAL FIELD

The present subject matter relates generally to lighting apparatuses and related methods and, more particularly, to solid state lighting apparatuses and related methods.

### BACKGROUND

Solid state lighting emitters are used in a variety of lighting apparatuses in, for example, commercial, automotive, and consumer lighting applications. Solid state emitters can comprise, for example, one or more unpackaged light emitting diode (LED) chips, one or more packaged LED chips, wherein the chips can comprise inorganic and/or organic LED chips (OLEDs). Solid state emitters generate light through the recombination of electronic carriers (electrons and holes) in a light emitting layer or region of an LED chip. LED chips have significantly longer lifetimes and a greater luminous efficiency than conventional incandescent and fluorescent light sources. However, as LED chips are narrow-bandwidth light emitters, it can be challenging to simultaneously provide good color rendering in combination with high luminous efficacy while maintain a maximizing brightness and efficiency.

Incandescent bulbs tend to produce a natural and aesthetically pleasing illumination compared to other types of conventional lighting apparatuses. In particular, incandescent bulbs typically range from a color temperature of about 2700K at full brightness, a color temperature of about 2000K at 5% brightness, and a color temperature of about 1800K at about 1% brightness. This compares favorably with daylight, which varies from about 6500K at midday to about 2500K at sunrise and sunset.

Research indicates that humans tend to prefer warmer color temperatures (e.g., approximately 2700K to 3000K) at low brightness levels in intimate settings. LED lighting manufacturers are challenged with providing lighting sources or apparatuses utilizing LED chips to generate light having a color behavior that approximates the behavior of incandescent lighting. Another challenge exists in achieving dimmable color behavior via LED chip based lighting apparatuses that approximate the dimmable characteristics of incandescent lighting.

Further challenges exist in achieving compact and/or thin LED chip based light sources configured to operate directly from an AC power source, where surge protection circuitry and/electrical components are provided over the compact/thin apparatus.

Accordingly, a need exists for smaller, thinner, and/or more compact solid state lighting apparatuses and/or improved methods including use and provision of solid state lighting apparatuses that can be directly coupled to an AC voltage signal and incorporate surge protection circuitry. Desirable apparatuses and methods would exhibit reduced cost and make it easier for end-users to justify switching to LED products from a return on investment or payback perspective.

### SUMMARY

Solid state lighting apparatuses and methods are provided herein. The apparatuses and methods can exhibit improved dimming capabilities, improved thermal management capabilities, and improved brightness. These and other objects are achieved at least in part according to the subject matter herein.

In one aspect, a solid state lighting apparatus is provided. The apparatus comprises a substrate, one or more surge protection components supported by the substrate, and at least one solid state light emitter supported by the substrate. The surge protection components are adapted to receive alternating current (AC) directly from an AC power source. The at least one solid state light emitter is electrically coupled to the one or more surge protection components. An overall height of the apparatus can for example be approximately 4 millimeters (mm) or less. In some aspects, an overall surface area of the one or more surge protection components can for example be approximately 168 square millimeters (mm²) or less. Surge protection circuitry described herein offers a compact form factor, compact surface area, is thin, and meets or exceeds Energy Star® standards.

A method of providing a solid state lighting apparatus is also disclosed. The method can comprise providing a substrate, providing one or more surge protection components over the substrate, arranging least one solid state light emitter over the substrate, and electrically coupling the at least one solid state light emitter to the one or more surge protection components. An overall height of the apparatus can for example be approximately 4 millimeters (mm) or less.

Other aspects, features and embodiments of the subject matter will be more fully apparent from the ensuing disclosure and appended claims. Apparatuses, systems, and methods provided herein can include improved dimming capabilities, improved thermal management capabilities, and improved brightness. These and other objects can be achieved according to the subject matter herein.

### BRIEF DESCRIPTION OF DRAWINGS

A full and enabling disclosure of the present subject matter is set forth more particularly in the remainder of the specification, including reference to the accompanying figures, relating to one or more embodiments, in which:

FIG. 1 is a schematic block diagram illustrating a solid state lighting apparatus according to some aspects;

FIG. 2 is a schematic circuit diagram illustrating the direct drive control circuitry as shown in FIG. 1 and LED segments coupled thereto according to some aspects;

FIGS. 3A and 3B are perspective and side views, respectively, illustrating a solid state lighting apparatus including multiple solid state light emitters and associated circuitry, on or over a substrate according to some aspects; and

FIGS. 4A to 4E are various views illustrating a solid state lighting apparatus including at least one solid state light emitter and associated circuitry, on or over a substrate according to some aspects.

### DETAILED DESCRIPTION

The present subject matter relates in certain aspects to solid state lighting apparatuses adapted to operate with alternating current (AC) received directly from an AC power source and related methods. Exemplary solid state lighting apparatuses can comprise a substrate and at least one solid state light emitter arranged on or supported by the substrate. Apparatuses described herein comprise novel surge protection circuitry and/or components integrated with and/or supported on the substrate thereby allowing for bright, thin, and/or compact apparatuses.

In some aspects, solid state lighting apparatuses and methods described herein can comprise various emitter configurations, color combinations, and/or circuit components adapted to reduce perceivable flicker, perceptible color shifts, and/or perceptible spatial variations in luminous flux that could potentially occur during activation and/or deactivation of multiple sets of different solid state light emitters.

In some aspects, solid state lighting apparatuses and methods herein comprise an overall height or thickness of approximately 4.5 millimeters (mm) or less, 4 mm or less, 3.7 mm or less, or less than 2.5 mm. Minimized components (e.g., resistors, fuses, etc.) as described herein advantageously reduce a mounting distance of the surge protection circuitry in regards to the light emitter surface, allows for a lower profile holder/cover that improves the allowable light delivered in a final form, and allows surge protection circuitry to reside on the same substrate as the integrated circuit (IC) driver component (e.g., power chip) and LED chips. Apparatuses and methods herein cost less, are more efficient, and are brighter than previous solutions.

Unless otherwise defined, terms used herein should be construed to have the same meaning as commonly understood by one of ordinary skill in the art to which this subject matter belongs. It will be further understood that terms used herein should be interpreted as having a meaning that is consistent with the respective meaning in the context of this specification and the relevant art, and should not be interpreted in an idealized or overly formal sense unless expressly so defined herein.

Aspects of the subject matter are described herein with reference to sectional, perspective, elevation, and/or plan view illustrations that are schematic illustrations of idealized aspects of the subject matter. Variations from the shapes of the illustrations as a result, for example, of manufacturing techniques and/or tolerances, are to be expected, such that aspects of the subject matter should not be construed as limited to particular shapes illustrated herein. This subject matter can be embodied in different forms and should not be construed as limited to the specific aspects or embodiments set forth herein. In the drawings, the size and relative sizes of layers and regions can be exaggerated for clarity.

Unless the absence of one or more elements is specifically recited, the terms “comprising,” “including,” and “having” as used herein should be interpreted as open-ended terms that do not preclude the presence of one or more elements. Like numbers refer to like elements throughout this description.

It will be understood that when an element such as a layer, region, or substrate is referred to as being “on” another element, it can be directly on the other element or intervening elements can be present. Moreover, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the apparatus in addition to the orientation depicted in the figures. For example, if the apparatus in the figures is turned over, structure or portion described as “above” other structures or portions would now be oriented “below” the other structures or portions.

The terms “electrically activated emitter” and “emitter” as used herein refer to any device capable of producing visible or near visible (e.g., from infrared to ultraviolet) wavelength radiation, including but not limited to, xenon lamps, mercury lamps, sodium lamps, incandescent lamps, and solid state emitters, including light emitting diodes (LEDs or LED chips), organic light emitting diodes (OLEDs), and lasers.

The terms “solid state light emitter” or “solid state emitter” refer to an LED chip, a laser diode, an organic LED chip, and/or any other semiconductor device preferably arranged as a semiconductor chip that comprises one or more semiconductor layers, which can comprise silicon, silicon carbide, gallium nitride and/or other semiconductor materials, a substrate which can comprise sapphire, silicon, silicon carbide and/or other microelectronic substrates, and one or more contact layers which can comprise metal and/or other conductive materials.

The terms “groups”, “segments”, or “sets” as used herein are synonymous terms. As used herein, these terms generally describe how multiple LED chips are electrically connected in series, in parallel, or in mixed series/parallel configurations among mutually exclusive groups/segments/sets.

The LED “segment” further refers to a separately switched portion of a string of LED chips. A segment can comprise at least one LED chip, which can itself comprise a number of serially connected epi junctions used to provide a chip that has a particular forward voltage, such as 3V, 6V, 9V, etc. where a single epi junction can have a forward voltage of about 1.5 volts. Each segment can also comprise multiple LED chips that are connected in various parallel and/or serial arrangements. The segments of LED chips can be configured in a number of different ways and can have various compensation circuits associated therewith, as discussed, for example, in commonly assigned and co-pending U.S. patent application Ser. No. 13/235,103 and U.S. patent application Ser. No. 13/235,127, the disclosure of each of which is hereby incorporated by reference herein.

The term “targeted” refers to configurations of LED chip segments that are configured to provide a pre-defined lighting characteristic that is a specified parameter for the lighting apparatus. For example, a targeted spectral power distribution can be a spectral power distribution that is specified for the light provided by the apparatus as a result of dimming the light. In particular, the targeted spectral power distribution can describe the characteristic of the light that is generated at a particular dimming level. In some aspects, the targeted spectral power distribution can be specified on the packaging of the lighting apparatus or otherwise in conjunction with the advertising or marketing of the lighting apparatus. Furthermore, the targeted spectral power distribution can be associated with the lighting characteristics of two or more specified dimming levels, such as a low light level and a higher light level. Accordingly, the targeted spectral power distribution can be provided as the light shifts from “full on” to more dimming as well a shift in the reverse direction toward “full on”.

LED chips can be characterized as having a particular spectral power distribution, which can affect various light characteristics of the light emitted by the chip. A spectral power distribution can be used to express the power per unit area per unit wavelength of an illumination (radiant exitance), or more generally, the per wavelength contribution to any radiometric quantity (such as radiant energy, radiant flux, radiant intensity, radiance, irradiance, radiant exitance, and/or radiosity, etc.). A spectral power distribution can be normalized in some manner, such as, to unity at 555 or 560 nanometers (nm), coinciding with the peak of the eye's luminosity function, in addition to the light characteristics described herein, such as CRI, CCT, CX and CY, etc.

In some aspects, LED segments are separately and/or selectively switched “on” and “off”, each of which can have a respective spectral power distribution and/or CCT color temperature. Further, at least one of the LED segments can be populated with LED chips of a particular spectral power distribution that is the target value for dimming. In operation, an LED segment drive circuit, for example, comprising a packaged drive circuitry (e.g., a power chip) can selectively switch the string current through the LED segments so that the overall spectral power distribution of light generated by the apparatus shifts toward a targeted spectral power distribution as dimming proceeds. LED segments can be activated and/or deactivated via a power chip during different portions of an AC waveform. For example, a full spectral power distribution can be provided by the power chip to switch current through a combination of one or all of the LED segments.

The term “substrate” as used herein in connection with lighting apparatuses refers to a mounting member or element on which, in which, or over which, multiple solid state light emitters (e.g., LED chips) can be arranged, supported, and/or mounted. Exemplary substrates useful with lighting apparatuses as described herein comprise printed circuit boards (including but not limited to metal core printed circuit boards, flexible circuit boards, dielectric laminates, ceramic based substrates, ceramic based substrates with PCB overlays, and the like) having electrical traces arranged on one or multiple surfaces thereof, support panels, and mounting elements of various materials and conformations arranged to receive, support, and/or conduct electrical power to solid state emitters. Electrical traces described can visible and/or not-visible in a final form, as such can be covered via a reflective covering, such as a solder mask and/or retention dam.

In some aspects, a single, unitary substrate can be used to support multiple groups of solid state emitters and can further be used to support related circuits and/or circuit elements, such as driver circuit elements, controller circuitry, surge protection circuitry, and/or dimmer circuit elements housed within a power chip.

Solid state lighting apparatuses according to aspects of the subject matter herein can comprise III-V nitride (e.g., gallium nitride) based LED chips or laser chips fabricated on a silicon, silicon carbide, sapphire, or III-V nitride growth substrate, including (for example) chips manufactured and sold by Cree, Inc. of Durham, N.C. Such LED chips and/or lasers can be configured to operate such that light emission occurs through the substrate in a so-called “flip chip” orientation. Such LED and/or laser chips can also be devoid of growth substrates (e.g., following growth substrate removal).

LED chips useable with lighting apparatuses as disclosed herein can comprise horizontal structures (with both electrical contacts on a same side of the LED chip) and/or vertical structures (with electrical contacts on opposite sides of the LED chip). A horizontally structured chip (with or without the growth substrate), for example, can be flip chip bonded (e.g., using solder) to a carrier substrate or printed circuit board (PCB), or wire bonded. A vertically structured chip (without or without the growth substrate) can have a first terminal solder bonded to a carrier substrate, mounting pad, or printed circuit board (PCB), and have a second terminal wire bonded to the carrier substrate, electrical element, or PCB.

Electrically activated light emitters, such as solid state emitters, can be used individually or in groups to emit one or more beams to stimulate emissions of one or more lumiphoric materials (e.g., phosphors, scintillators, lumiphoric inks, quantum dots) to generate light at one or more peak wavelengths, or of at least one desired perceived color (including combinations of colors that can be perceived as white). Inclusion of lumiphoric (also called ‘luminescent’) materials in lighting apparatuses as described herein can be accomplished by an application of a direct coating of the material on lumiphor support elements or lumiphor support surfaces (e.g., by powder coating, inkjet printing, or the like), adding such materials to lenses, and/or by embedding or dispersing such materials within lumiphor support elements or surfaces. Methods for fabricating LED chips having a planarized coating of phosphor integrated therewith are discussed by way of example in U.S. Patent Application Publication No. 2008/0179611 to Chitnis et al., the disclosure of which is hereby incorporated by reference herein in the entirety.

Other materials, such as light scattering elements (e.g., particles) and/or index matching materials can be associated with a lumiphoric material-containing element or surface. Apparatuses and methods as disclosed herein can comprise LED chips of different colors, one or more of which can be white emitting (e.g., including at least one LED chip with one or more lumiphoric materials).

In some aspects, one or more short wavelength solid state emitters (e.g., blue and/or cyan LED chips) can be used to stimulate emissions from a mixture of lumiphoric materials, or discrete layers of lumiphoric material, including red, yellow, and green lumiphoric materials. LED chips of different wavelengths can be present in the same group of solid state emitters, or can be provided in different groups of solid state emitters.

Dimming effects, where the CCT of the light source changes when dimmed, can be achieved by mixing red/orange (RDO), amber, blue shifted yellow (BSY), warm white, and other LED chips or die that produce different colors in a direct drive configuration are provided. In a dim to warm example, LED chips combine to produce a desired end CCT point will be used and connected to a direct drive controller, such as a power chip. In low dimming instances, one string will be the only string active in a direct drive topology. As the other strings turn on, cooler LED chips are used to increase the color temperature. This change in CCT will behave in the opposite manner as the dimming level is decreased. Mixing different color LED chips in different targeted strings will allow for color change while dimming and increase the CRI of the LED source.

The expression “peak wavelength”, as used herein, means (1) in the case of a solid state light emitter, the peak wavelength of light that the solid state light emitter emits if it is illuminated, and (2) in the case of a lumiphoric material, the peak wavelength of light that the lumiphoric material emits if it is excited.

A wide variety of wavelength conversion materials (e.g., luminescent materials, also known as lumiphors or lumiphoric media, e.g., as disclosed in U.S. Pat. No. 6,600,175 and U.S. Patent Application Publication No. 2009/0184616), are well-known and available to persons of skill in the art. Examples of luminescent materials (lumiphors) comprise phosphors, scintillators, day glow tapes, nanophosphors, quantum dots (e.g., such as provided by NNCrystal US Corp. (Fayetteville, Ark.)), and inks that glow in the visible spectrum upon illumination with (e.g., ultraviolet) light. One or more luminescent materials useable in apparatuses as described herein can be down-converting or up-converting, or can comprise a combination of both types.

Aspects relating to the subject matter disclosed herein can be better understood with reference to the 1931 CIE (Commission International de l'Eclairage) Chromaticity Diagram, which is well-known and readily available to those of ordinary skill in the art. The 1931 CIE Chromaticity Diagram maps out the human color perception in terms of two CIE parameters, namely x and y. The spectral colors are distributed around the edge of the outlined space, which comprises all of the hues perceived by the human eye. The boundary line represents maximum saturation for the spectral colors. The chromaticity coordinates (i.e., color points) that lie along the blackbody locus obey Planck's equation: E(λ)=A λ⁻⁵/(e^{B/T}−1) where E is the emission intensity, A is the emission wavelength, T the color temperature of the blackbody, and A and B are constants. Color coordinates that lie on or near the blackbody locus yield pleasing white light to a human observer. The 1931 CIE Diagram comprises temperature listings along the blackbody locus (embodying a curved line emanating from the right corner). These temperature listings show the color path of a blackbody radiator that is caused to increase to such temperatures. As a heated object becomes incandescent, it first glows reddish, then yellowish, then white, and finally bluish. This occurs because the wavelength associated with the peak radiation of the blackbody radiator becomes progressively shorter with increased temperature, consistent with the Wien Displacement Law. Illuminants, such as apparatuses disclosed herein, which produce light that is on or near the blackbody locus can be described in terms of their color temperature.

The expression “lighting apparatus” as used herein, is not limited, except that it is capable of emitting light. That is, a lighting apparatus can be a device or apparatus that illuminates an area or volume, e.g., a structure, a swimming pool or spa, a room, a warehouse, an indicator, a road, a parking lot, a vehicle, signage, e.g., road signs, a billboard, a ship, a toy, a mirror, a vessel, an electronic device, a boat, an aircraft, a stadium, a computer, a remote audio device, a remote video device, a cell phone, a tree, a window, an LCD display, a cave, a tunnel, a yard, a lamppost, or a device or array of devices that illuminate an enclosure, or a device that is used for edge or back-lighting (e.g., backlight poster, signage, LCD displays), light bulbs, bulb replacements (e.g., for replacing AC incandescent lights, low voltage lights, fluorescent lights, etc.), outdoor lighting, security lighting, exterior residential lighting (wall mounts, post/column mounts), ceiling fixtures/wall sconces, under cabinet lighting, lamps (floor and/or table and/or desk), landscape lighting, track lighting, task lighting, specialty lighting, rope lights, ceiling fan lighting, archival/art display lighting, high vibration/impact lighting-work lights, etc., mirrors/vanity lighting, or any other light emitting device.

In some aspects, a lighting apparatus as described herein is devoid of any AC-to-DC converter in electrical communication between the AC power source and multiple sets (e.g., disposed in an array) of solid state light emitters. In some aspects, a lighting apparatus as described herein comprises at least one driving circuit (or multiple driving circuits in some aspects) packaged or housed within a chip (e.g., an integrated circuit (IC) power chip) and arranged in electrical communication between an AC source and multiple sets of solid state light emitters. In some aspects, a lighting apparatus as described herein comprises at least one rectifier bridge (or multiple rectifier bridges in some aspects) arranged in electrical communication between an AC source and multiple sets of solid state light emitters for rectifying the AC signal.

In some aspects, a lighting apparatus as described herein comprises at least one solid state emitter or multiple emitters configured to be activated and/or deactivated at different times relative to one another during a portion of an AC cycle, and each set of the multiple sets comprises at least a first solid state light emitter segment targeting a first color and at least a second solid state light emitter segment targeting a second color that is different than the first color. In some aspects, each set of the multiple sets comprises at least two solid state light emitters of a same color (e.g., the peak wavelengths coincide). In some aspects, each set of the multiple sets of solid state emitters is adapted to emit one or more different color(s) of light. In some aspects, each set of the multiple sets of solid state emitters is adapted to emit one or more color(s) of light that differ relative to one another (e.g., with each set of solid state emitters emitting at least one peak wavelength that is not emitted by another set of solid state emitters).

In some aspects, a lighting apparatus as described herein comprises multiple sets of solid state light emitters that are configured to be activated and/or deactivated at different times relative to one another during a portion of an AC cycle, and the lighting apparatus comprises an output of at least approximately 100 lumens per watt (LPW) or more, least about 120 LPW or more, at least approximately 130 LPW or more, at least approximately 140 LPW or more, more than approximately 150 LPW, or more than 200 LPW. One or more of the foregoing LPW thresholds are attained for emissions having at least one of a cool white (CW) color temperature or a warm white (WW) color temperature. White emissions of apparatuses herein have x, y color coordinates within four, seven, or ten MacAdam step ellipses of a reference point on the blackbody locus of a 1931 CIE Chromaticity Diagram. Apparatuses described herein can be powered via approximately 10 watts (W) or more and/or 25 W or less.

In some aspects, apparatuses described herein can emit white light having a reference point on the blackbody locus (e.g., 1931 CIE Chromaticity Diagram) can have a color temperature of less than or approximately equal to 5000 K, less than or approximately equal to 4000 K, less than or approximately equal to 3500 K, less than or approximately equal to 3000 K, or less than or approximately equal to 2700 K. In some aspects, combined emissions from a lighting apparatus as described herein embody a color rendering index (CRI Ra) value of at least 70, at least 75, or at least 80 (e.g., 82 or 85) or more.

In some aspects, LED segments are positioned sequentially according to an increasing or decreasing color temperature, or CCT, across apparatuses described herein. Such placement can be beneficial to improve dimming, and/or can be beneficial for managing heat dissipation from a lighting apparatus (e.g., as differently colored chips can be activated/deactivated at different times, thereby minimizing hot spots). Various illustrative features are described below in connection with the accompanying figures.

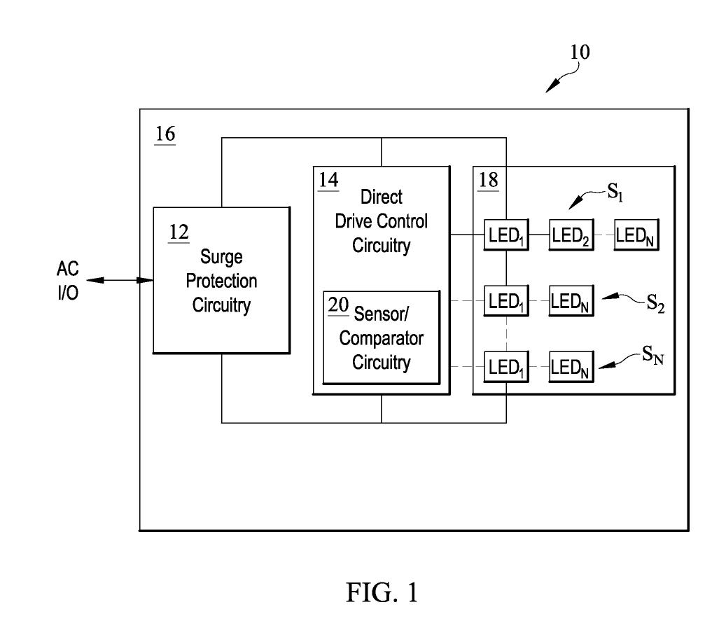

FIG. 1 is a schematic block diagram illustrating a solid state lighting apparatus, generally designated 10, according to some aspects of the present subject matter. Solid state lighting apparatus 10 can comprise surge protection circuitry 12 and direct drive control circuitry 14. Surge protection circuitry 12 and direct drive control circuitry 14 can be at least substantially coplanar with respect to each other over a common substrate 16, and directly coupled to one or more LED segments, generally designated S₁, S₂, S_{N}, disposed within a light emitter area 18 of apparatus 10. Any number of LED segments S₁, S₂, S_{N} (where N is an integer >1) can be provided per apparatus 10. Each segment S₁, S₂, S_{N} can comprise at least one LED chip (e.g., LED₁) or multiple LED chips (e.g., LED₁ to LED_{N}, where N is an integer >1). Light emitter area 18 comprises a portion or area of substrate from which light is emitted via at least one solid state light emitter.

Direct drive control circuitry 14 can comprise sensor/comparator circuitry 20. Sensor/comparator circuitry 20 can be configured to monitor the line voltage (e.g., AC in/out or “AC I/O”) and determine when to switch LED chips on/off during a portion of an AC waveform.

Surge protection circuitry 12, direct drive control circuitry 14, and at least one LED chip disposed within light emitter area 18 can each be mounted, arranged, and/or otherwise supported over one or more surfaces of a substrate 16. The term “mounted on” as used herein comprises configurations where the component, such as an LED chip or submount of a LED package, can be physically and/or electrically connected to a portion of substrate 16 via solder, epoxy, silicone, adhesive, glue, paste, combinations thereof and/or any other suitable attachment material and/or method. Various components or elements are described as being “mounted on” substrate 16 and can be disposed on the same surface of the same substrate 16, on opposing surfaces of the same substrate 16, or on adjacent surfaces of the same substrate 16. For example, components that are placed and soldered on the same substrate during assembly can be described as being “mounted on” that substrate.

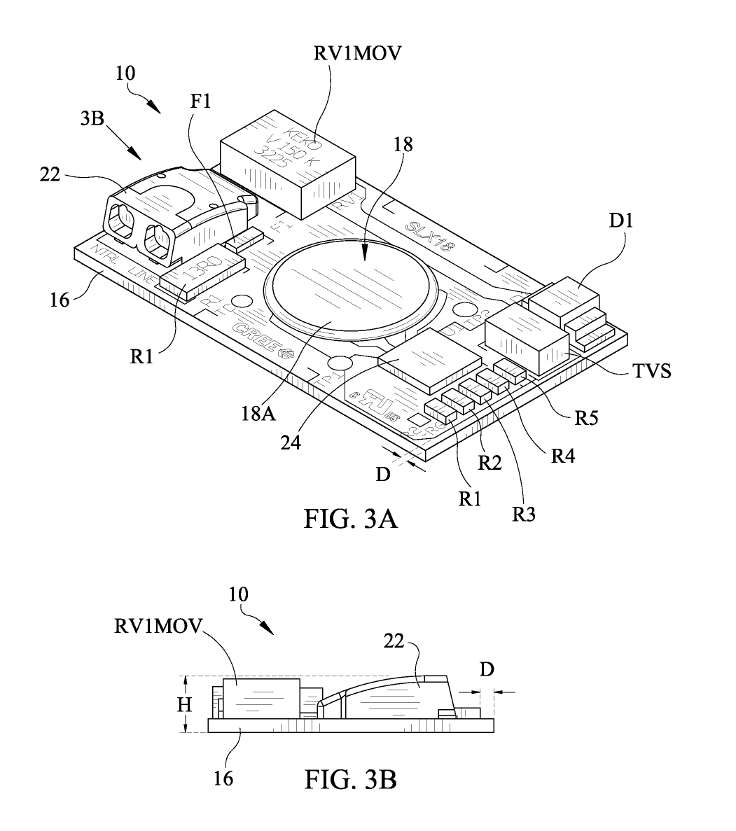

Surge protection circuitry 12 can comprise one or more electrical components, elements, or circuit members adapted for reducing and/or eliminating transmission of voltage transients or voltage spikes exceeding the line voltage from reaching direct drive control circuitry 14, LED segments S₁, S₂, S_{N}, and/or components thereof. Surge protection circuitry protects direct drive control circuitry 14 (e.g., a power chip, 24 of FIG. 3A) and/or LED chips within one or more LED segments S₁, S₂, S_{N} from voltage spikes.

In some aspects, surge protection circuitry is disposed on substrate 16 and comprises one or more resistors, fuses, metal-oxide varistor (MOV), bridge rectifiers (e.g., diode bridge rectifiers), transient voltage suppression (TVS) diodes, varistor MOV, combinations thereof, and/or any other type of component/circuit, which can implement surge protection capabilities. Notably, apparatus 10 and components disposed thereon can comprise an overall height or thickness of approximately 4.5 mm or less, 4 mm or less, 3.7 mm or less, and/or 2.5 mm or less. Apparatuses described herein are brighter, thinner, and more compact than conventional apparatuses.

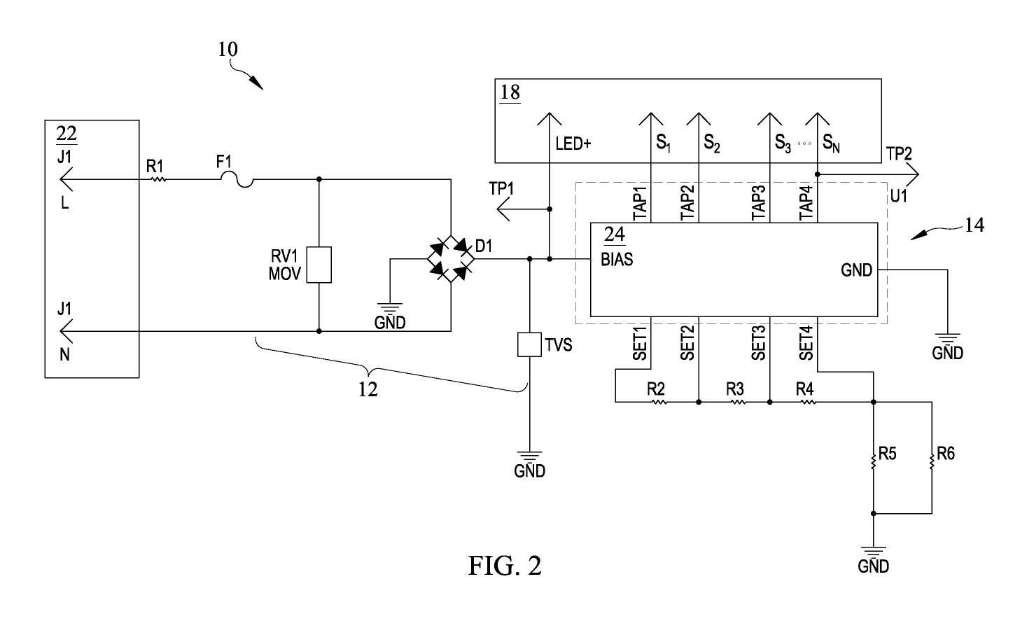

An electrical AC voltage power source can provide an alternating electrical signal (current and voltage) directly to apparatus 10. In some aspects, AC voltage signal is provided to a rectifier circuit of surge protection circuitry 12, such as for example, a diode bridge (D1, FIG. 2) of apparatus 10. Diode bridge (D1, FIG. 2) and other surge protection components can also be disposed over and/or mounted on substrate 16 for providing a rectified AC voltage signal directly to direct drive control circuitry 14 for driving LED chips of light emitter area 18 via a rectified (positive waveform), thereby reducing perceptible flicker, for example, during dimming or otherwise switching current through LED segments. Control circuitry 14 is adapted to switch current through LED segments S₁, S₂, S_{N}, for example, by pushing more current into some segments and/or by bypassing other segments. In other aspects, control circuitry 14 can supply different, variable amounts of current to each LED segment S₁, S₂, S_{N}. In some aspects, circuitry 14 can be adapted to activate and/or deactivate different LED segments S₁, S₂, S_{N} of multiple segments, during different portions of an AC waveform.

Direct drive control circuitry 14 can comprise at least one packaged or housed integrated circuit component, such as a power chip (e.g., 24, FIGS. 2 and 3A), configured to supply electrical current to each LED segment S₁, S₂, S_{N}. Each LED segment S₁, S₂, S_{N} can receive a same amount of electrical current or different amounts of electrical current at various times via direct drive control circuitry 14 for achieving a desired amount of illumination, color, and/or color temperature from each of the plurality segments. In some aspects, direct drive control circuitry 14 supplies current to some LED segments S₁, S₂, S_{N} and does not supply current to other LED segments S₁, S₂, S_{N}, such that some segments can remain dark or “off”. In some aspects, each LED segment S₁, S₂, S_{N} is individually controlled for providing any illumination level and/or color temperature between a fully “on” state and any dimmed state that is below the fully “on” state.

Direct drive control circuitry 14 can control an amount of electrical current collectively and/or individually supplied to LED segments S₁, S₂, S_{N} in response to a change in line voltage, a control signal, an input, or any other control parameter as detected at comparator circuitry 20. For example, direct drive control circuitry 14 can supply current collectively and/or individually to one or more LED segments S₁, S₂, S_{N} in response to activation or physical movement of a dimmer switch, a pre-set condition, a user-defined condition, one or more inputs or other control parameters, any perceptible change in line voltage, or a sensor arranged to sense or detect electrical, optical, environmental and/or thermal properties.

In some aspects, direct drive control circuitry 14 can comprise what is referred to as a “smart” power chip (e.g., 24, FIGS. 2 and 3A). The power chip is configured to monitor the input voltage and determine at what times or portions of a rectified AC waveform LED segments S₁, S₂, S_{N} should be switched “on” and “off”. Comparator circuitry 20 is configured to monitor the power or input voltage via monitoring the AC line in (e.g., AC I/O), and determine when to supply current to, change an amount of current supplied to, bypass current to, and/or switch on/off the one or more LED segments S₁, S₂, S_{N}. In some aspects, direct drive control circuitry 14 can comprise a control circuit adapted to issue control commands for activating and/or deactivating LED segments S₁, S₂, S_{N} in response to processing the monitored changes of input voltage.

LED segments S₁, S₂, S_{N} can be coupled in series or parallel between direct drive control circuitry 14. LED segments S₁, S₂, S_{N}, one or more portions of surge protection circuitry 12, and/or portions of direct drive control circuitry 14 can be at least partially coated with a reflective coating and/or be disposed below or within a portion of a reflective structure for reducing or eliminating impingement of light generated by LED chips within LED segments S₁, S₂, S_{N} onto components of apparatus.

It is appreciated that various aspects described herein can make use of the direct application of AC voltage to apparatus 10 (e.g., from an outside power source, not shown) without the inclusion of an “on-board” switched mode power supply. That is, various aspects relate to apparatuses that are devoid of a discrete AC-to-DC converter in electrical communication between the AC power source and the multiple groups or segments of LED chips. In some aspects, a rectified AC waveform is supplied directly to control circuitry 14 and LED segments S₁, S₂, S_{N} for generating acceptable light output from apparatus 10. Solid state lighting apparatus 10 can be utilized in light bulbs, lighting devices, lighting products, lighting components and/or lighting fixtures of any suitable type.

In some aspects, apparatus 10 is also devoid of one or more discrete energy storage devices disposed over substrate 16, such as one or more discrete electrolytic capacitors or inductors. Direct drive control circuitry 14 can integrate storage and/or current diversion circuitry into a single package or power chip. For example, direct drive control circuitry 14 can comprise an IC package or chip which obviates the need for discrete capacitors and/or inductors. This can advantageously increase the amount of space over substrate 16 available for LED chips (e.g., thereby increasing brightness) and decrease the cost associated with manufacturing apparatus 10. In addition to these benefits, apparatuses that are devoid of one or more electrolytic capacitors benefit from an increased lifetime (e.g., as capacitors are typically a lifetime-limiting component), as well as allowing smaller sizes to accommodate a given brightness level.

LED segments S₁, S₂, S_{N} can accommodate any desired voltage level and different voltage levels for different applications. For illustration purposes, apparatus 10 is operable at both 120V and 240V and/or any range therebetween. LED segments S₁, S₂, S_{N} are configured to be activated and/or deactivated at different times relative to one another during a portion of an AC cycle, and are configured to operate within about 3 percent or more of a root mean square (RMS) voltage of the AC power source. In certain aspects, the AC power source has a nominal RMS voltage of at least about 100V, such as including approximate values of 90V, 110V, 120V, 170V, 220V, 230V, 240V, 277V, 300V, 480V, 600V higher voltages, or any approximate or subset of voltage as previously recited. Each LED segment S₁, S₂, S_{N} of apparatus 10 can be operable at any voltage level, and can be operable at a same or different voltage levels. In some aspects, the voltage at which the collective LED segments S₁, S₂, S_{N} operate can add or sum to the line voltage (e.g., “AC I/O” in FIG. 1).

FIG. 2 is a schematic circuit diagram of apparatus 10, which illustrates in more detail at least some of the circuitry associated with surge protection circuitry 12, direct drive control circuitry 14, and/or LED segments S₁, S₂, S_{N}. LED segments S₁, S₂, S_{N} can be provided in light emitter area 18 disposed over a common substrate with surge protection circuitry 14 and direct drive control circuitry 14. A receiver or connector 22 can also be provided over apparatus 10, and over a common substrate with emitter area 18 and circuitry components.

In some aspects, surge protection circuitry 12 comprises at least a first resistor R1 and/or a first fuse F1. First resistor R1 can for example comprise a 13 ohm (Ω) and 1.5 Watt (W) power rated device. In some aspects, resistor R1 is approximately 0.7 mm in height or less, such as for example commercially available from Vishay Intertechnology, Ltd., having United States headquarters in Shelton, Conn. All thicknesses or heights provided herein can vary within approximately +/−0.5 mm due to manufacturing differences. First resistor R1 can be surge rated for enhanced pulse load capability.

In some aspects, first fuse F1 can comprise a 3 Amp (A), 125V fast blow fuse. Apparatus 10 can initially pass current through first resistor R1, prior to passing current through serially connected first fuse F1. First resistor R1 can impart surge protection to first fuse F1 while also allowing a smaller fuse to be used. A smaller fuse F1 can reduce the cost associated with apparatus 10, as well as increase the amount of space available on apparatus 10 for LED chips, thereby improving brightness and light extraction per apparatus 10. Smaller fuses also reduce the mounting distance of the protection circuitry in regards to a light emitter surface (e.g., 18A, FIG. 3A) of light emitter area 18. Smaller fuse F1 further allows for lower profile holders/covers, maximize light by minimizing blockage of light, and allow surge protection circuitry 14 to reside on a same surface as other components, including LED chips. In some aspects, fuse F1 is approximately 0.8 mm in height or less, such as for example commercially available from Bel Fuse Inc., having its corporate office in Jersey City, N.J.

Still referring to FIG. 2 and in some aspects, surge protection circuitry 12 further comprises one or more rectifier bridges, such as a diode bridge D1. AC current can pass into apparatus 10 via a receiver or connector 22, and across first resistor R1 and first fuse F1 prior to entering diode bridge D1. In some aspects, diode bridge D1 is a bridge rectifier of approximately 3 mm in height or less, such as for example commercially available from Fairchild Semiconductor Corporation, headquartered in San Jose, Calif.

In some aspects, surge protection circuitry 12 further comprises a metal oxide varistor designated RV1 MOV. RV1 MOV is connected in parallel to diode bridge D1. In some aspects, RV1 MOV is configured reduce and/or eliminate transmission of voltage transients exceeding the line voltage provided to control circuitry 14 and/or LED segments S₁, S₂, S_{N}. In some aspects, RV1 MOV is approximately 3.7 mm in height or less, such as for example commercially available from Keko Varicon, headquartered in \check{Z}u\check{z}emberk, Slovenia. In other aspects, an alternative to RV1 MOV can be used for providing surge protection to components of apparatus 10, for example, a CH series varistor (e.g., an alternate, low-profile MOV) having a height of approximately 2.03 mm or less manufactured by Littlefuse Inc., based in Chicago, Ill. may also be used.

As FIG. 2 illustrates and in some aspects, surge protection circuitry 12 further comprises one or more transient voltage suppression (TVS) diodes, designated TVS. TVS can protect direct drive control circuitry 14 (e.g., including a power chip) and LED chips from voltage spikes and/or voltage transient events. In some aspects, TVS is approximately 2.44 mm in height or less, such as for example commercially available from Littlefuse Inc., based in Chicago, Ill.

In some aspects, components of surge protection circuitry 12 (e.g., R1, F1, RV1 MOV, D1, TVS, etc.) can comprise surface mount design (SMD) and/or surface mount technology (SMT) components. This is advantageous, as the components can mount directly over surfaces of substrate 16 (FIGS. 1, 3A) via solder, adhesive, or other materials/methodology, while the amount of space occupied over substrate 16 by each component is minimized. In some aspects, the total surface area of surge protection circuitry 12 (e.g., R1, F1, RV1 MOV, D1, TVS, etc.) can be approximately 168 mm² or less, approximately 150 mm² or less, or approximately 100 mm² or less.

Surge protection circuitry 12 is compact (e.g., having a total area of approximately 168 mm² or less) and has a surge compatibility level that is compliant with the Energy Star® surge test level of 2.5 kV Line-Neutral Ring Wave, as well as the IEC61547 and IEC 61000-4-5 surge level of 500V Line-Neutral combination wave </=25 W.

Current can pass through surge protection circuitry 12 and/or components thereof directly into direct drive control circuitry 14. Direct drive control circuitry 14 can comprise a power chip 24 including a sensor or comparator circuit 20 (FIG. 1) for monitoring the line voltage and supplying current to LED segments S₁, S₂, S_{N}. As noted above, direct drive control circuitry can be encapsulated and/or housed within a single IC package such as a QFN package, a DFN package, or a MLP. Power chip 24 can comprise one or more input or set lines, generally designated SET1, SET2, SET3, SET4, etc., in addition to one or more output or tap lines, generally designated TAP1, TAP2, TAP3, TAP4, etc. The plurality of set lines can be configured to control an amount of current that is routed or pushed into each LED segment S₁, S₂, S_{N} via respective tap lines. Set and tap lines are also configured to bypass some LED segments S₁, S₂, S_{N} while supplying current and thereby activating other LED segments. The plurality of tap lines can be configured to pass current directly into respective LED segments S₁, S₂, S_{N}. In some aspects, an amount of current supplied to each LED segments S₁, S₂, S_{N} can be selectively controlled for producing any desired illumination and/or color point. In some aspects, each LED segment S₁, S₂, S_{N} can be mutually exclusive from each other LED segment, allowing for individualized control thereof. Any number of LED segments (e.g., up to “N” total) can be provided per apparatus 10. Each segment can comprise at least one LED chip.

Direct drive circuitry 14 may further comprise a plurality of resistors (e.g., designated R2 to R6, where R6 is optional). Resistors R2 to R6 can be disposed outside of power chip 24 (e.g., as illustrated in FIG. 3A) and assist in regulating current flow and lowering voltage levels within drive circuitry.

Still referring to FIG. 2, in some aspects LED segments S₁, S₂, S_{N} are provided within a light emitter area 18. Emitter area 18 can comprise one or more electrically conductive pads, traces, and/or electrically conductive portions of substrate (e.g., 16, FIG. 1) for supplying current to at least one LED chip and/or an array of LED chips. LED segments S₁, S₂, S_{N} can comprise mutually exclusive and/or separately switchable LED segments. The segments can be electrically coupled in series with one another, or in parallel with one another, or in combinations thereof. Each segment S₁, S₂, S_{N} can comprise at least one LED chip serially connected to each other via direct drive control circuitry 14. In some aspects, each segment S₁, S₂, S_{N} comprises a plurality of LED chips, such as more than two LED chips, more than four LED chips, more than 6 LED chips, or more than 10 LED chips. In some aspects, each LED segment S₁, S₂, S_{N} is configured to emit light having a particular, targeted CCT value. In some aspects, at least one targeted LED segment S₁, S₂, S_{N} is configured to shift the characteristic of the light generated by apparatus 10 from any full targeted spectral power distribution to, for example, a targeted spectral power distribution, as dimming proceeds. In some aspects, the targeted spectral power distribution can be provided using LED chips in the targeted segment that have particular CRI values, CCT values, efficacy values, S/P ratios (i.e., scotopic to photopic ratios), or any other lighting characteristic that is intended to be specified as a target light for dimming.

At least one electrostatic discharge (ESD) protection device LED+ can be provided per apparatus 10, and reverse biased with respect to LED chips within each LED segment S₁, S₂, S_{N}. ESD protection device LED+ can be configured to protect LED chips within each LED segment from damage, due to an ESD event or events.

As FIG. 2 further illustrates, apparatus 10 can comprise one or more test points, designated TP1 and TP2. Test points TP1 and TP2 comprise exposed, electrically conductive portions of substrate, by which optical and/or electrical properties of apparatus 10 can be measured.

In some aspects, each LED segment S₁, S₂, S_{N is} separately switchable “on” or “off” during different portions of a rectified AC waveform at any voltage. For example, a first segment S₁, a second segment S₂, a third segment S₃, and a fourth segment S₄ (e.g., of “N” segments) can be configured for inclusion in the lighting apparatus operating from a 120V or 240V power source. As disclosed above, apparatus 10 is operable at any desired voltage for accommodating desired relatively higher and/or lower voltage applications (e.g., 120V applications, 240V applications, more than 240V lighting applications). In some aspects according to the present subject matter, the switching can be provided using the techniques described in commonly assigned U.S. Pat. No. 8,476,836, the disclosure of which is incorporated herein by reference.

Notably, each LED segment S₁, S₂, S_{N} can be configured to emit a different CCT color temperature for improved dimming. Each LED chip within each respective segment can target approximately a same CCT value. For example, and in some aspects, first segment S₁ can be configured to emit light comprising a CCT value targeting approximately 1800K. Second and third segments S₂ and S₃ can be configured to emit slightly cooler light, for example, comprising CCT values targeting approximately 2100K and 2400K, respectively. Fourth segment S₄ is configured to emit slightly cooler light targeting approximately 3000K. Where apparatus 10 targets approximately 3000K, fourth segment S₄ can be configured to emit light targeting more than approximately 3000K. When each segment is powered “on”, together the four segments S₁, S₂, S₃, and S₄ are collectively configured to emit warm white light that is tuned or targeted to approximately 2700K and/or approximately 3000K. As each segment turns from “on” to “off”, light warms from approximately 2700K (e.g., alternatively, 3000K) to 1800K as it dims, halogen-style. Thus, apparatus 10 emits light that is pleasing to consumers, and perceptible flicker during dimming is reduced via electrical components supported over substrate 16 (FIG. 1).

In some aspects, LED chips within each LED segment S₁, S₂, S_{N} target a same or approximately a same CCT value. That is, first segment S₁ can comprise multiple serially connected LED chips, where each intra-string chip comprises a CCT value of approximately 1800K. Similarly, second, third, and fourth segments S₂, S₃, and S₄, respectively, comprise intra-string chips having CCT values targeting approximately 2100K, 2400K, and 3000K, respectively. Direct drive control circuitry 14 is configured to control light output and/or color by switching LED segments on/off (i.e., activating/deactivating), and allocating power among the segments such that the light generated shifts from the full spectral power distribution toward a targeted spectral power distribution that is pre-defined by the LED chips included in the targeted LED segment. Where a targeted spectral power is that of first segment S₁ (e.g., approximately 1800K), more power will be allocated to that LED segment. Similarly, where a targeted spectral power is between or an average of first and second segments (e.g., around 2000K), then more power will be allocated to first and second segments, S₂ and S₃, respectively.

FIG. 3A is a top perspective view of solid state lighting apparatus 10 illustrating one embodiment of a layout of emitter area generally designated 18, surge protection components or circuitry 12 (e.g., R1, F1, RV1 MOV, D1, TVS) and power chip 24. Apparatus 10 can comprise a substantially rectangular substrate 16 over which a substantially circular light emitter area 18 having a substantially circular light emitter surface 18A can be provided, for example, as described in commonly assigned and co-pending U.S. Pat. No. 8,564,000, U.S. Pat. No. 8,624,271, and U.S. patent application Ser. No. 13/282,172, the disclosure of each of which is hereby incorporated by reference herein.

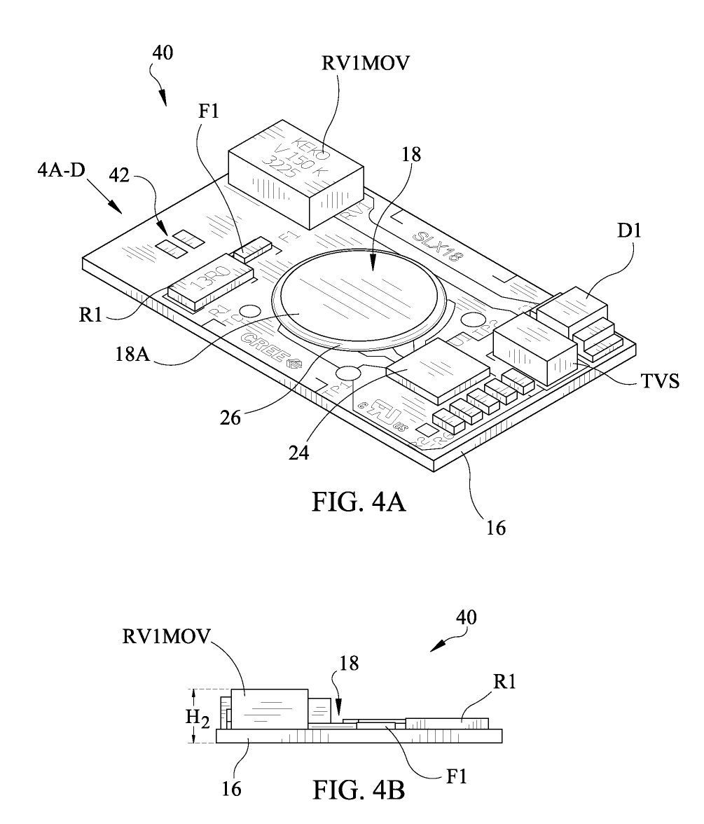

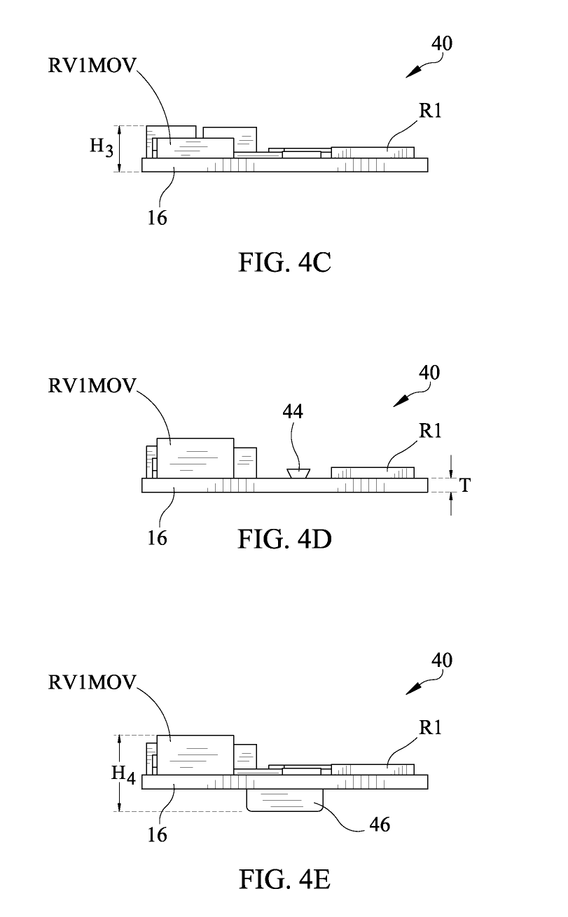

Light emitter area 18 comprises one or more LED chips (not shown) provided within LED segments (e.g., S₁, S₂, S_{N}, FIGS. 1 and 2) over a mounting area comprising one or more traces. FIG. 3A is illustrative of various electrical components, circuitry, and encapsulated LED chips/segments. Light emitter area 18 comprises LED chips encapsulated or otherwise covered with an optical element. Thus, LED chips and/or LED segments S₁, S₂, S_{N} may not be visible in the final, fully manufactured form as illustrated in FIGS. 3A and 4A. LED chips can be encapsulated within silicone, epoxy, which may or may not contain lumiphoric material, such as one or more phosphors. LED segments within emitter area 18 can be switchable on/off at different times during an AC waveform by virtue of connection to different tap lines (e.g., TAP1 to TAP4) of power chip 24.

As FIG. 3A illustrates, power chip 24 can comprise a flat no-lead IC package, for example, a quad-flat no-lead (QFN) surface mount package, a dual-flat no-lead (DFN) surface mount package, and/or a micro leadframe package (MLP). Such packages are configured to physically and electrically connect to portions of substrate 16 via electrically conductive members, portions, and/or surfaces thereof, such as exposed metallic leads. Flat no-lead packages refer to packages having leadframe substrates, however, the “leads” are not externally extending from lateral sides of the package, for example, in a J-bend or gull-wing type configuration. Rather, power chip 24 can comprise a near chip sized package having a planar copper lead frame substrate encapsulated in plastic. Perimeter leads on a bottom surface of the encapsulated package are not visible from outside of apparatus 10, but provide a direct electrical connection between circuitry 14 and other electrical components provided on or over substrate 16 and diode bridge D1. In some aspects, power chip 24 further comprises an exposed thermal pad on a bottom surface thereof for improving heat transfer out of the chip and into substrate 16. In some aspects, one or more through holes or “vias” can be provided in the substrate 16 directly below portions of power chip 24 for improving thermal management within apparatus 10.

Power can be supplied to power chip 24 via a receiver or connector 22 supported by or on substrate 16. The receiver can comprise a circuit or circuit component (e.g., a portion of circuitry 12 or 14, FIGS. 1 and 2) that is adapted to receive AC directly from an AC power source. The receiver or connector 22 can receive and direct current to power chip 24 and one or more LED segments S₁, S₂, S_{N}. In some aspects, the receiver comprises a connector 22, which receives power directly from the AC power source. The current is then rectified and passed into the LED chips. Connector 22 can comprise one or more openings in which input wires carrying AC power can be received and directly connected. Wires from an AC power source can directly connect with apparatus 10 via connector 22.

Emitter area 18 can comprise LED segments (e.g., S₁ to S_{N}, FIG. 1) or chips (e.g., LED₁ to LED_{N}, FIG. 1) provided within a portion of a reflective retaining member 26. Retaining member 26 can comprise a wall, a dam, or a dispensed retention material. Emitter area 18 comprises one or more LED segments (e.g., S₁ to S_{N}, FIG. 4) provided below an optical element, such as a lens or encapsulant. That is, in this view, LED segments (e.g., S₁ to S_{N}, FIG. 1) and underlying traces/mounting pad of substrate 16 are not visible, as each can be provided below portions of optical element (e.g., light emitter surface 18A) and/or reflective retaining member 26. Notably, retaining member 26 can, but does not have to, comprise a phosphoric or lumiphoric material for further affecting or tuning light output. In some aspects, a layer of encapsulant dispensed over LED chips between portions of retaining member 26.

In some aspects, light emitter surface 18A can comprise a substantially yellow appearance via the phosphoric material contained therein. In some aspects, more than one type of phosphor can be provided over LED chips of emitter area 18. Light emitter surface 18A can comprise any one of a yellow, green, blue, or red phosphor, and/or combinations thereof. Light emitter area 18A can comprise substantially uniform layers of phosphor, or non-uniform layers of phosphor. Light emitter surface 18A can comprise a substantially planar light emitter surface from which light is emitted. Light emitter surface 18A can comprise any suitable diameter, such as approximately 10 mm or more, 20 mm or more, 30 mm or more, 40 mm or more, 48 mm or more, or more than approximately 50 mm. Light emitter surface 18A can be approximately centered with respect to substrate 16. In some aspects, more than one light emitter area 18 and, therefore, more than one light emitter surface 18A can be provided per apparatus 10. In other aspects, a non-centered light emitter surface 18A or a non-centered emitter area 18 can be provided over apparatus 10.

As FIG. 3A illustrates, current can initially be directed from connector 22 across first resistor R1 and first fuse F1 prior entering surge protection circuitry including RV1 MOV, diode bridge D1, and TVS, each of which is supported via a single, common substrate 16. Connector 22, first resistor R1, first fuse F1, and RV1 MOV can be provided at one end (e.g., a first end) of substrate, while D1, TVS, and power chip 24 can be provided at another, second end of substrate 16. Light emitter area 18 can be provided between the first and second ends, proximate a center of substrate. Diode bridge D1 is configured to rectify the AC power for providing a rectified AC waveform. A portion of the current can be routed from connector 22 to surge protection circuitry RV1 MOV and TVS. Surge protection circuitry components D1, RV1 MOV and TVS can reduce or eliminate transmission of voltage transients exceeding the line voltage provided to the LED segments within emitter area 18.

In some aspects, substrate 16 comprises a non-metallic ceramic based substrate, for example, alumina (Al₂O₃), high reflectivity alumina, or any other suitable ceramic or ceramic based material. Surge protection components (e.g., R1, F1, D1, RV1 MOV, TVS, etc.) and/or driver components (e.g., power chip 24) can be spaced from the non-metallic ceramic based substrate body by one or more non-metallic layers Non-metallic layers can comprise FR-4, fiberglass reinforced epoxy, polyimide, or a PCB laminate material. In some aspects, substrate 16 comprises a non-metallic, ceramic based body having a non-metallic overlay adhered thereto, as discussed, for example, in commonly assigned and co-pending U.S. patent application Ser. No. 13/836,709 and U.S. patent application Ser. No. 13/836,940, the disclosure of each of which is hereby incorporated by reference herein.

In other aspects, substrate 16 comprises multiple layers of material, where at least one layer is a ceramic or a dielectric base layer. Substrate 16 can comprise any suitable material, such as ceramic, Al, Alanod (e.g., Al and Ag), etc., having one or more layers, such as traces provide thereon. In some aspects, substrate 16 comprises a PCB, a MCPCB, a laminate structure having one or more layers connected via adhesive, a flexible printed circuit board (“flextape” PCB) comprising a polymer-like film having at least one conductive layer within one or more layers of a flexible plastic resin (e.g., polyimide, Kapton from DuPont), and one or more adhesive layers comprising a tape-like adhesive provided on the flextape for easy connection to a ceramic body. In some aspects, substrate 16 can comprise a ceramic base having one or more (e.g., and optionally flexible) layers adhered thereon.

The layout or design of apparatus 10 can vary and/or become selectively changed for maximizing space over substrate 16. Maximizing space can allow lighting designers to increase or decrease a size or diameter of light emitter area 18, for changing optical properties, such as brightness. In some aspects, each electrical component, for example, fuses, resistors, diodes (e.g., bridge diode D1 and TVS), traces, circuitry, surge protection circuitry 14, wires, and power chip 24 are each spaced a distance, designated D inboard of each outermost edge of substrate 16. In some aspects, distance D comprises at least approximately 1.6 millimeters (mm) in compliance with Underwriters Laboratory (UL®) testing standards and/or for meeting UL® spacing requirements.

In some aspects, LED segments (e.g., S₁, S₂, S_{N}, FIG. 1) within emitter area 18 can comprise a plurality of “chip-on-board” (COB) LED chips electrically coupled or connected in series or parallel with one another and mounted on a portion of substrate 16. In some aspects, COB LED chips can be mounted directly on portions of substrate 16 without the need for additional packaging. For example, in some aspects emitter area 18 comprises serial and/or parallel arrangements of differently colored LED chips available from Cree, Inc. of Durham N.C. In some aspects, each LED segment (S₁, S₂, S_{N}, FIG. 1) is serially connected to other segments via power chip 24. In other aspects, each LED segment is electrically connected in parallel with other segments via power chip 24.

Notably, and as FIG. 3B illustrates, apparatus 10 can comprise an overall thickness or height H, which in some aspects is a sum of the respective heights of substrate 16 and connector 22. In some aspects, substrate 16 comprises a thickness of approximately 1.2 mm or less. However, any thickness is contemplated. Overall height H can be approximately 4.5 mm or less (including substrate 16), As FIG. 3B illustrates, in some aspects connector 22 is the main contributor to overall height H of apparatus 10, however, in some aspects, apparatuses may be devoid of a raised connector (e.g., FIGS. 4A to 4E). Electrical components, such as resistors, fuses, diodes (e.g., D1, TVS) can be spaced at least a distance D inboard of substrate edges, where D is at least approximately 1.6 mm.

FIGS. 4A to 4E illustrate further embodiments of a solid state light emitter apparatus, generally designated 40. Solid state apparatus 40 is similar in form and function to apparatus 10, however, it is devoid of a raised receiver or an electrical connector (e.g., 22, FIG. 3A). Rather, apparatus 40 can comprise one or more substantially flat receivers or electrically conductive attachment areas, generally designated 42. Attachment areas 42 can be substantially planar with an upper surface of substrate 16, and comprise solder pads, traces, and/or any other circuitry element by which portions of an AC power source can electrically connect. In some aspects, connectors (e.g., wires) of an AC power source can be soldered, welded, adhered, clamped, or otherwise secured to attachment areas 42. Attachment areas can electrically communicate with surge protection circuitry (e.g., 12, FIG. 1), control circuitry (e.g., 14, FIG. 1) comprising power chip 24, and LED chips of emitter area 18 for illuminating emitter area 18.

As FIG. 4B illustrates, apparatus 40 can comprise an overall height H₂, which in some aspects is a sum of the respective heights of substrate 16 and surge circuitry or components, such as the tallest component of RV1 MOV, TVS, R1, F1, D1, etc. Overall height H₂ can be approximately 4 mm or less (including a thickness of substrate 16), where RV1 MOV is the main contributor to the overall height. As apparatus 40 is devoid of a connector (e.g., 22, FIG. 3A), the overall height can be further reduced.

FIG. 4C illustrates an embodiment of apparatus 40, where a thinner RV1 MOV can be used for providing surge protection to components of apparatus 40, for example, a CH series MOV (e.g., a low-profile varistor or MOV) having a height of approximately 2 mm or less (e.g., 2.03 mm) can be provided. Thus, RV1 MOV is no longer the main component contributing to overall height. As FIG. 4C illustrates, apparatus 40 can comprise an overall height H₃, which in some aspects is a sum of the respective heights of substrate 16 and components on a front surface thereof. Overall height H₃ can be approximately 3.7 mm or less (e.g., 3.65), or less than 3.5 mm. In some aspects as FIG. 4C illustrates, D1 or TVS may be the main contributor to height. Height of apparatus 40 can thus be reduced by using a smaller, thinner RV1 MOV as shown in FIG. 4C and/or a smaller, thinner connector 42, also shown in FIGS. 4A to 4E.

FIG. 4D illustrates an embodiment of apparatus 40 in which only a single LED chip 44 is provided over substrate 16. Substrate 16 comprises a thickness T, of approximately 1.2 mm or less. However, any thickness T can be provided. Rather than multiple LED chips and/or segments, apparatus 40 can comprise at least a single LED chip disposed over a same surface of substrate 16 as surge protection and control circuitry.

FIG. 4E illustrates a side view of another embodiment of apparatus 40. As FIG. 4E illustrates, one or more electrical components 46 can be provided on a rear or backside of apparatus 40, which opposes the front side upon which solid state emitters can be provided. In some aspects, electrical components 46 comprise surge protection circuitry or components (e.g., RV1 MOV, D1, TVS, a low-profile MOV, a series fuse, a series resistor, etc.). Apparatus 40 comprises a height, H₄, which can vary between approximately 2 mm and 5 mm. In some aspects, overall height H₄ comprises thicknesses of substrate 16 and components on front/back surfaces of apparatus. In some aspects, overall height H₄ is less than approximately 4.5 mm, 4 mm, or 3.7 mm.

In some aspects, substrate 16 can be provided in any relatively compact form factor (e.g., square, rectangle, circular, non-square, non-circular, symmetrical and/or asymmetrical) considering at one LED chip 44 can be provided thereon. For example, substrate 16 can comprise a rectangle shape or configuration of approximately 20 mm×40 mm, such as approximately 23.75 mm×41.25 mm. In some aspects, apparatuses described herein comprise a light emitter surface (e.g., 18A, FIG. 3A) of approximately 48 mm in diameter as provided over an approximately 24 mm×41 mm rectangular board or substrate 16.

Further, the resulting board or substrate 16 with at least one LED chip 44 provided thereon and operated by the direct application of AC voltage signal (i.e., without an on-board switched mode power supply) can provide an efficient output apparatus 10 and/or 40 that can deliver approximately 100 LPW or more in select color temperatures, such as between approximately 1800K and 3000K (i.e., nominally 2700K). In some aspects, substrate 16 can comprise a form factor suitable for replacement of standard light bulbs, elongated fluorescent tube-type bulbs, or replacement of fluorescent light fixtures.

When dimming is applied via segmental bypassing and/or selective electrical current routing via power chip 24, apparatuses 10 and 40 can be dimmed so that the emitted light can more closely approximates incandescent lighting when, for example, the minimum value CCT LED chips are “warm” in color such as that provided by LED chips having a CCT value of about 1800K or a CX and CY of about (0.55, 0.41).

In some aspects, apparatuses 10 and 40 as described herein can deliver approximately 1000 lumens or more and have an efficiency ranging from between approximately 100 LPW and about 150 LPW at warm white temperatures of approximately 1800K to 3000K. In some aspects, apparatuses 10 and 40 described herein can deliver more than approximately 500 lumens, more than approximately 1000 lumens, more than approximately 1200 lumens, more than approximately 1600 lumens, or more than approximately 2000 lumens. It is understood that in some aspects, however, that greater output can be achieved by, for example, increasing the number of LED chips or by increasing the current signal or level used to drive the LED chips provided within apparatuses 10 and 40. A greater output can also be achieved by, for example, incorporating reflective structures, reflective coatings, optical diffusers, remote phosphors, or wavelength conversion material (e.g., phosphor(s), lumiphors(s), etc.) over portions of each apparatus as described further below.

In some aspects, apparatuses 10 and 40 described herein may be provided and/or disposed inside of a reflective holder or cover, as shown and described in commonly owed, assigned, and co-pending U.S. Design patent application Ser. No. 29/484,056, which is incorporated by reference herein, in the entirety.

Aspects as disclosed herein can provide one or more of the following beneficial technical effects: reduced cost of solid state lighting apparatuses; reduced size or volume of solid state lighting apparatuses; reduced perceptibility of flicker of solid state lighting apparatuses operated with AC power; reduced perceptibility of variation in intensity (e.g., with respect to area and/or direction) of light output by solid state lighting apparatuses operated with AC power; reduced perceptibility of variation (e.g., with respect to area and/or direction) in output color and/or output color temperature of light output by solid state lighting apparatuses operated with AC power; improved dissipation of heat (and concomitant improvement of operating life) of solid state lighting apparatuses operated with AC power; improved manufacturability of solid state lighting apparatuses operated with AC power; improved ability to vary color temperature of emissions of solid state lighting apparatuses operated with AC power; improved light extraction; reduced absorption of light by driver circuitry components; and reduced impingement of light upon driver circuitry or electrical components of a solid state lighting apparatus.

While the subject matter has been has been described herein in reference to specific aspects, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein.

Various combinations and sub-combinations of the structures and features described herein are contemplated and will be apparent to a skilled person having knowledge of this disclosure. Any of the various features and elements as disclosed herein can be combined with one or more other disclosed features and elements unless indicated to the contrary herein. Correspondingly, the subject matter as hereinafter claimed is intended to be broadly construed and interpreted, as including all such variations, modifications and alternative embodiments, within its scope and including equivalents of the claims.

What is claimed is:

1. A solid state lighting apparatus, comprising:
a substrate;
one or more surge protection components supported by the substrate, wherein the surge protection components are adapted to receive alternating current (AC) directly from an AC power source; and
at least one solid state light emitter supported by the substrate and electrically coupled to the one or more surge protection components;
wherein an overall height of the apparatus is approximately 4.5 millimeters (mm) or less.

2. The apparatus of claim 1, wherein the surge protection components comprise a first resistor serially connected to a first fuse.

3. The apparatus of claim 2, wherein the first resistor is disposed in a surge protection circuit in advance of the first fuse.

4. The apparatus of claim 1, comprising a plurality of light emitters provided in a plurality of light emitter segments.

5. The apparatus of claim 4, wherein at least one light emitter segment targets a color temperature of approximately 2700K or below and another light emitter segment targets a color temperature of approximately 2700K or above.

6. The apparatus of claim 4, wherein at least one solid state light emitter segment targets a color temperature of approximately 1800K.

7. The apparatus of claim 1, wherein the substrate comprises a non-metallic body, and wherein the one or more surge protection components are spaced from the non-metallic body by one or more non-metallic layers.

8. The apparatus of claim 7, wherein at least one of the non-metallic layers comprises FR-4, fiberglass reinforced epoxy, polyimide, or a PCB laminate material.

9. The apparatus of claim 1, wherein the surge protection components comprise at least one of a metal-oxide varistor (MOV), a bridge rectifier, a transient voltage suppression (TVS) diode, and/or a combination thereof.

10. The apparatus of claim 1, further comprising at least one packaged driver component arranged on a surface of the substrate.

11. The apparatus of claim 10, wherein the packaged driver component and at least one surge protection component are disposed over coplanar surfaces of the substrate.

12. The apparatus of claim 1, wherein the at least one solid state light emitter is encapsulated.

13. The apparatus of claim 1, wherein at least one phosphor is disposed over the at least one solid state light emitter.

14. The apparatus of claim 1, wherein the substrate comprises ceramic.

15. The apparatus of claim 14, wherein the ceramic comprises alumina (Al₂O₃).

16. The apparatus of claim 1, wherein the overall height of the apparatus is approximately 4 mm or less.

17. The apparatus of claim 1, wherein the overall height of the apparatus is approximately 3.7 mm or less.

18. A solid state lighting apparatus, comprising:
a substrate;
one or more surge protection components supported by the substrate, wherein the surge protection components are adapted to receive alternating current (AC) directly from an AC power source; and
at least one solid state light emitter supported by the substrate and electrically coupled to the one or more surge protection components;
wherein a total surface area of the one or more surge protection components is approximately 168 square millimeters (mm²) or less.

19. The apparatus of claim 18, wherein total surface area the one or more surge protection components is approximately 150 mm² or less.

20. The apparatus of claim 18, wherein total surface area the one or more surge protection components is approximately 100 mm² or less.

21. The apparatus of claim 18, wherein an overall height of the apparatus is approximately 4.5 millimeters (mm) or less.

22. The apparatus of claim 21, wherein the overall height of the apparatus is approximately 4 mm or less.

23. The apparatus of claim 21, wherein the overall height of the apparatus is approximately 3.7 mm or less.

24. The apparatus of claim 18, wherein the surge protection components comprise a first resistor serially connected to a first fuse.

25. The apparatus of claim 24, wherein the first resistor is disposed in a surge protection circuit in advance of the first fuse.

26. The apparatus of claim 24, wherein the surge protection components further comprise at least one of a metal-oxide varistor (MOV), a bridge rectifier, a transient voltage suppression (TVS) diode, and/or a combination thereof.

27. The apparatus of claim 26, wherein a height of each component of the surge protection components is approximately 3.7 mm or less.

28. The apparatus of claim 18, comprising a plurality of light emitters provided in a plurality of light emitter segments.

29. The apparatus of claim 28, wherein at least one light emitter segment targets a color temperature of approximately 2700K or below and another light emitter segment targets a color temperature of approximately 2700K or above.

30. The apparatus of claim 28, wherein at least one solid state light emitter segment targets a color temperature of approximately 1800K.

31. The apparatus of claim 18, further comprising at least one packaged driver component arranged on a surface of substrate.

32. The apparatus of claim 18, wherein the substrate comprises ceramic.

33. The apparatus of claim 32, wherein the ceramic comprises alumina (Al₂O₃).

34. A method of providing a solid state lighting apparatus, the method comprising:
providing a substrate;
providing one or more surge protection components over the substrate;
arranging least one solid state light emitter over the substrate; and
electrically coupling the at least one solid state light emitter to the one or more surge protection components;
wherein an overall height of the apparatus is approximately 4.5 millimeters (mm) or less.

35. The method of claim 34, wherein providing the substrate comprises providing a non-metallic substrate.

36. The method of claim 34, wherein providing the substrate comprises providing an alumina (Al₂O₃) substrate.

37. The method of claim 34, wherein providing the surge protection components comprises providing at least one of a resistor, a fuse, a metal-oxide varistor (MOV), a bridge rectifier, a transient voltage suppression (TVS) diode, and/or a combination thereof.

38. The method of claim 37, wherein a total surface area of the one or more surge protection components is approximately 168 square millimeters (mm²) or less.

39. The apparatus of claim 34, wherein a height of each component of the surge protection components is approximately 4 mm or less.

39. The apparatus of claim 34, wherein a height of each component of the surge protection components is approximately 3.7 mm or less.
